(19) United States
(12) Patent Application Publication
(10) Pub. No.: US 2026/0262348 A1
(43) Pub. Date: Sep. 3, 2026

(54) SEMICONDUCTOR LIGHT EMITTING DEVICE AND METHOD FOR MANUFACTURING SEMICONDUCTOR LIGHT EMITTING DEVICE

(71) Applicant: STANLEY ELECTRIC CO., LTD., Meguro-ku, Tokyo (JP)

(72) Inventor: Daisuke WATANABE, Tokyo (JP)

(73) Assignee: STANLEY ELECTRIC CO., LTD., Meguro-ku, Tokyo (JP)

(21) Appl. No.: 18/877,591

(22) PCT Filed: Jun. 1, 2023
(86) PCT No.: PCT/JP2023/020555

§ 371 Date: Dec. 20, 2024

(30) Foreign Application Priority Data
Jun. 23, 2022 (JP) 2022-101254

(51) Int. Cl. H10H 20/856; H10H 20/01; H10H 20/851; H10H 20/852; H10H 20/857

(52) U.S. Cl. CPC H10H 20/856; H10H 20/021; H10H 20/0362; H10H 20/0364; H10H 20/851; H10H 20/852; H10H 20/857

(57) ABSTRACT

The present invention provides a semiconductor light emitting device which has high light emission efficiency and in which reflectivity of a lead frame rarely decreases due to corrosion. An insulating connection member 13 that adheres a bottom surface of a light emitting element 12 to an upper surface of a first electrode 11a is photoreflective, extends to a region outside of an external shape of a rectangle of the light emitting element 12, and covers a part of a region of a surface of the first electrode 11a outside of the light emitting element 12.

### TECHNICAL FIELD

The present invention relates to a semiconductor light emitting device having a structure in which a semiconductor light emitting element is fixed on a lead frame by an adhesive member and a periphery is sealed with resin.

### BACKGROUND ART

Semiconductor light emitting devices that have structures in which semiconductor light emitting elements are fixed on lead frames by adhesive members have been known. For example, according to PTL 1 and PTL 2, a semiconductor light emitting element is fixed on a lead frame by an adhesive member, and a photoreflective thermosetting resin frame formed by transfer molding is mounted at a position away by a predetermined distance from the semiconductor light emitting element. Semiconductor light emitting device that has a structure in which a space between the semiconductor light emitting element and the frame is filled with transparent resin containing a phosphor substance is disclosed.

In the semiconductor light emitting device having such structure, light emitted from the semiconductor light emitting element is reflected partially from the frame and partially from the surface of the lead frame to be emitted upward. Therefore, to improve upward emission efficiency, it is disclosed that metal plating such as silver and aluminum is applied to the surface of the lead frame to enhance reflection efficiency.

### CITATION LIST

### Patent Literature

PTL 1: JP2010-62272A
PTL 2: JP2006-156704A

### SUMMARY OF INVENTION

### Technical Problem

The lead frames plated with silver and aluminum may be corroded by oxygen, moisture, nitrogen oxide, sulfur oxide, and the like in the atmosphere, which causes a decrease in reflectivity of the surfaces of the lead frames and a decrease in light output of the light emitting devices. Therefore, the decrease in light reflectivity due to corrosion of the lead frames can be prevented by performing gold plating with corrosion resistance. However, since the gold-plated frames have low reflectivity of blue light, light output of the light emitting devices decreases.

An object of the present invention is to provide a semiconductor light emitting device that is capable of maintaining a light output even in a structure in which gold plating is performed on a lead frame for corrosion prevention and is rarely susceptible to an influence of decrease in reflectivity due to corrosion even in a structure in which gold plating for corrosion prevention is not performed on the surface of the lead frame.

### Solution to Problem

To achieve the above object, a semiconductor light emitting device according to an aspect of the present invention includes: a resin molded body having a depression; a pair of electrodes disposed inside the resin molded body and formed of a lead frame in which a part of a surface is exposed from a bottom portion of the depression; a light emitting element mounted on a first electrode in the pair of electrodes; and an insulating connection member configured to adhere a bottom surface of the light emitting element to an upper surface of the first electrode. The connection member is photoreflective. The connection member extends to a region outside of an external shape of a rectangle of the light emitting element and covers a part of a region of a surface of the first electrode outside of the light emitting element.

### Advantageous Effects of Invention

According to the present invention, it is possible to provide a semiconductor light emitting device that is capable of maintaining a light output even in a structure in which gold plating for corrosion prevention is performed on a lead frame because part of light emitted from a side surface of a light emitting element is reflected from a photoreflective connection member extending to outside of the light emitting element, and that maintains a light output and is rarely susceptible to an influence of a decrease in reflectivity due to corrosion of a surface of the lead frame even in a structure in which the gold plating for corrosion prevention is not performed.

### BRIEF DESCRIPTION OF DRAWINGS

FIGS. 1 (a), (b), (c), and (d) are a top view, a side view from a long side, a side view from a short side, and a rear view illustrating a semiconductor light emitting device according to a first embodiment, and (e) is a sectional view.

FIG. 2 (a) is a top view illustrating an example of a light emitting element of the semiconductor light emitting device according to the first embodiment, and (b) is a sectional view.

FIGS. 3 (a) and (b) are diagrams illustrating directivity of the light emitting element of the semiconductor light emitting device according to the first embodiment.

FIGS. 4 (a) and (b) are a top view and a sectional view of a part of the semiconductor light emitting device according to the first embodiment.

FIG. 5 (a) is a top view illustrating a lead frame of the semiconductor light emitting device according to the first embodiment, and (b) to (d) are sectional views illustrating the lead frame.

FIG. 6 is a flowchart illustrating a manufacturing process for the semiconductor light emitting device 1 according to the first embodiment.

FIG. 7 is a top view illustrating the manufacturing process for the semiconductor light emitting device 1 according to the first embodiment.

FIG. 8 is a top view illustrating the manufacturing process for the semiconductor light emitting device 1 according to the first embodiment.

FIG. 9 is a top view illustrating the manufacturing process for the semiconductor light emitting device 1 according to the first embodiment.

FIG. 10 is a top view illustrating the manufacturing process for the semiconductor light emitting device 1 according to the first embodiment.

FIG. 11 is a top view illustrating the manufacturing process for the semiconductor light emitting device 1 according to the first embodiment.

FIGS. 12 (a) to (c) and (e) are sectional views illustrating the manufacturing process for the semiconductor light emitting device 1 according to the first embodiment and (d) is a top view.

FIG. 13 is a top view illustrating the manufacturing process for the semiconductor light emitting device 1 according to the first embodiment.

FIG. 14 is a top view illustrating the manufacturing process for the semiconductor light emitting device 1 according to the first embodiment.

FIG. 15 is a top view illustrating the manufacturing process for the semiconductor light emitting device 1 according to the first embodiment.

FIG. 16 is a table illustrating light outputs of semiconductor light emitting devices according to the first embodiment and Comparative Example 1.

### DESCRIPTION OF EMBODIMENTS

A semiconductor light emitting device according to embodiments of the present invention will be described below.

### First Embodiment

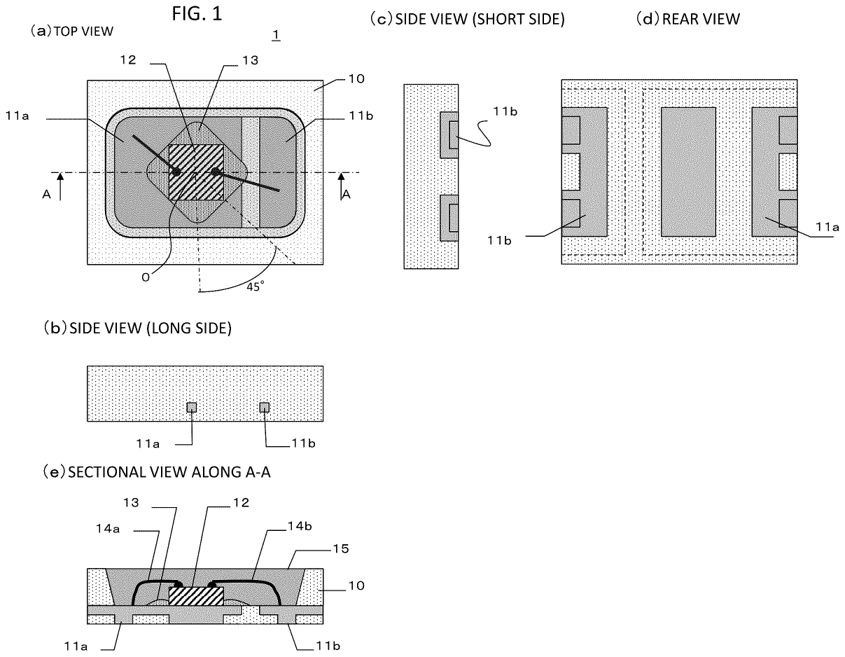

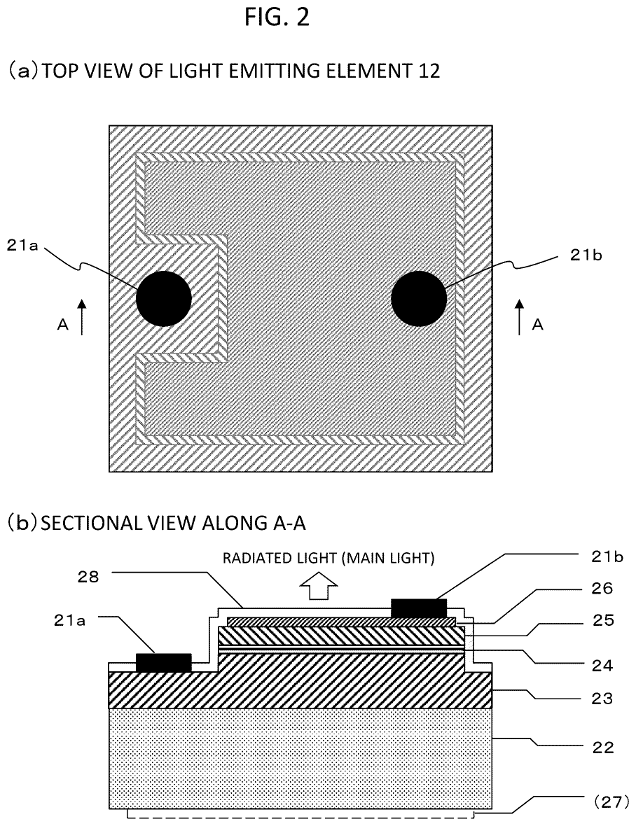

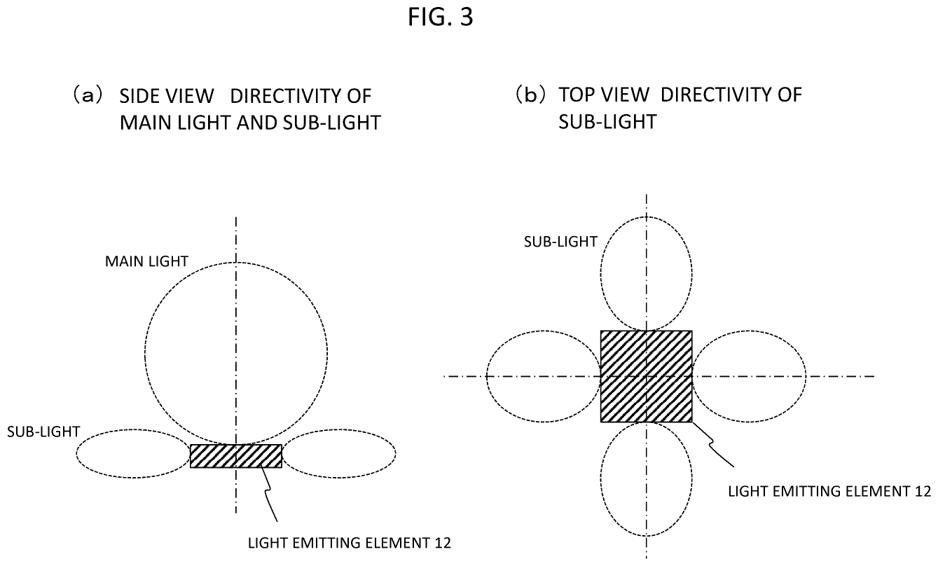

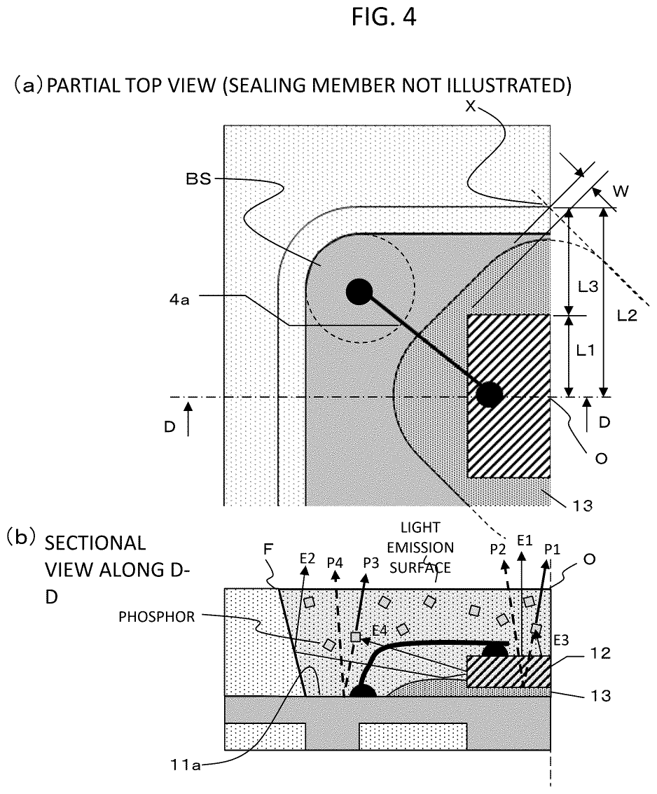

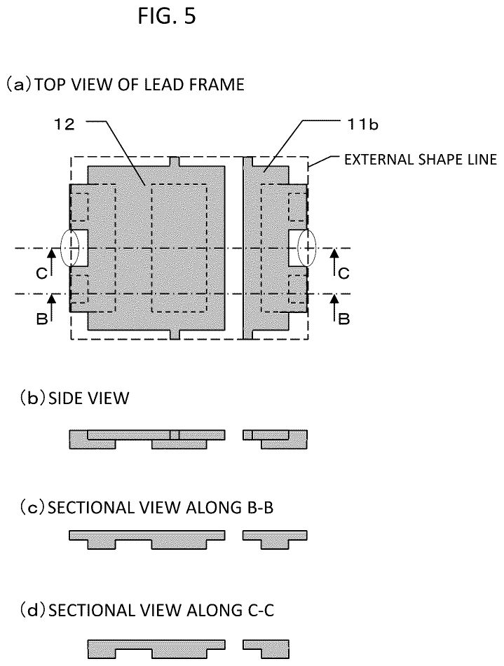

A configuration of a semiconductor light emitting device 1 according to a first embodiment will be described with reference to FIGS. 1 to 5. FIGS. 1(a), (b), (c), and (d) are a top view, a side view from a long side, a side view from a short side, and a rear view illustrating a semiconductor light emitting device 1, and FIG. 1(e) is a sectional view. FIG. 2(a) is a top view illustrating an example of a light emitting element, and FIG. 2(b) is a sectional view. FIGS. 3(a) and (b) are diagrams illustrating directivity of the light emitting element. FIGS. 4(a) and (b) are a top view and a sectional view of a part of the semiconductor light emitting device 1 and also illustrate a light path. FIGS. 5(a) to (d) are a top view and sectional views illustrating a lead frame. In FIGS. 1, 2, 4, and 5, hatching is drawn to facilitate understanding of a structure even in a top view.

The semiconductor light emitting device 1 according to the first embodiment includes a frame 10 that is a resin molded body, a pair of electrodes 11a and 11b formed by a lead frame, a light emitting element 12, an insulating adhesive member 13, and a sealing member 15, as in FIG. 1.

The frame 10 has a depression at the center. The pair of electrodes 11a and 11b are disposed inside the frame 10 and parts of surfaces are exposed from the bottom portion of the depression. The frame 10 covers a part of rear surface sides of the electrodes 11a and 11b, and also fills a space between the electrodes 11a and 11b to insulate both electrodes. The external shape of the frame 10 is rectangular when viewed from above, and four outer surfaces of the frame 10 are perpendicular to main planes of the electrodes 11a and 11b. On outer side surfaces of long sides of the frame 10, end surfaces of the first electrode 11a and the second electrode 11b are positioned on the same plane as the outer surfaces of the frame 10.

In the pair of electrodes 11a and 11b, the first electrode 11a serves as a cathode and the second electrode 11b serves as an anode. The surfaces of the pair of electrodes 11a and 11b are subjected to gold (Au) plating with corrosion resistance and having reflection characteristics in which reflectivity of light with a longer wavelength than blue light is high.

The light emitting element 12 is a semiconductor light emitting element that emits, for example, blue light with a main wavelength of 440 nm to 460 nm and is mounted on the first electrode 11a in the pair of electrodes 11a and 11b exposed from the bottom portion of the depression.

The adhesive member 13 has a reflective property reflecting light in a visible light band and is disposed between the bottom surface of the light emitting element 12 and the upper surface of the first electrode 11a to adhere the light emitting element 12 to the first electrode 11a. The adhesive member 13 has a shape extending from the space between the bottom surface of the light emitting element 12 and the upper surface of the first electrode 11a to a region outside of the external shape of a rectangle of the light emitting element 12. Accordingly, the adhesive member 13 extending to the region outside of the light emitting element 12 covers a part of the region of the surface of the first electrode 11a outside of the light emitting element 12.

An n-side electrode pad (cathode) 21a and a p-side electrode pad (anode) 21b that are element electrodes are formed on the upper surface of the light emitting element 12. One end of a first bonding wire 14a is connected to the n-side electrode pad 21a. The other end of the first bonding wire 14a is connected to a region that is an upper surface of the first electrode 11a and is not covered with the adhesive member 13. One end of a second bonding wire 14b is connected to the p-side electrode pad 21b. The other end of the second bonding wire 14b is connected to the upper surface of the second electrode 11b. Accordingly, a drive current is supplied from the first electrode 11a and the second electrode 11b to the light emitting element 12 via the first bonding wire 14a and the second bonding wire 14b.

Inside of the depression of the frame 10 is filled with the sealing member 15 so that the light emitting element 12, the first bonding wire 14a, and the second bonding wire 14b are buried.

In the sealing member 15, a light conversion member is dispersed in resin that is transparent for light emitted from the light emitting element 12. The light conversion member absorbs part of the light emitted from the light emitting element 12 and radiates light with a longer wavelength than the absorbed light. The light conversion member is, for example, a phosphor that emits yellow light that is a complementary color of blue light radiated by the light emitting element 12. A portion (upper surface) of the sealing member 15 exposed from the depression of the frame 10 is a light emission surface FO of the light emitting device 1.

### (Operational Effect of Each Unit During Light Emission)

When the drive current is supplied from the first electrode 11a and the second electrode 11b to the light emitting element 12 via the first bonding wire 14a and the second bonding wire 14b, the light emitting element 12 emits main light from the upper surface and sub-light from the side surfaces (see FIG. 3).

As in FIG. 3 (a), the main light is emitted upward from the upper surface of the light emitting element 12. The sub-light is emitted from each of four side surfaces of the light emitting element 12. The sub-light is light (sub-light) that is guided in an in-plane direction inside a growth substrate of the light emitting element 12 and the intensity of the sub-light is large in a direction of an axis which is perpendicular to the side surfaces of the light emitting element 12 and passes the center of each side of the light emitting element 12.

As illustrated in FIG. 4(b), main light (E1, E3) is emitted upward from the light emitting element 12, a part of the main light (E1) transmits through the sealing member 15 and is emitted upward as it is, the other part (E3) of the main light is radiated to a wavelength conversion member, the wavelength of the light is converted by the wavelength conversion member, and the converted light passes through the sealing member 15 and is emitted upward.

Of the sub-light (E2, E4), the sub-light E2 is emitted diagonally downward from the side surface of the light emitting element 12 and is reflected from the surface of the adhesive member 13 of the light emitting element 12 to be oriented upward, as illustrated in FIG. 4 (b). A wavelength of part of the sub-light E2 on the way upward is converted by the wavelength conversion member and part of the sub-light E2 is further reflected from the frame 10 to be oriented upward.

Since the sub-light E4 is emitted diagonally upward from the light emitting element 12, the sub-light E4 does not reach the adhesive member 13 and passes through the sealing member 15, the wavelength of part of the sub-light E4 is converted by the wavelength conversion member, and oriented upward directly or reflected upward by the frame 10.

Phosphor particles excited by the light emitted from the light emitting element 12 radiate yellow light in all directions of the phosphor. Here, light P3 that is radiated upward is emitted from the light emission surface FO of the light emitting device 1 and light P4 (yellow light) that is radiated downward is reflected from the surfaces of the adhesive member 13, the first electrode 11a, and the second electrode 11b to be emitted from the light emission surface FO of the light emitting device 1.

In the above description, even when the sealing member 15 does not include the wavelength conversion member and when light emitted from the light emitting element 12 is all converted by the wavelength conversion member, same effects can be expected.

As such, in the semiconductor light emitting device 1 according to the first embodiment, sub-light emitted diagonally downward among the sub-light emitted from the side surfaces of the light emitting element 12 is reflected from the adhesive member 13. Therefore, there is no influence of reflection characteristics of the first electrode 11a and the second electrode 11b subjected to metal plating (here, gold plating) with corrosion resistance, and thus it is possible to improve a light output of the semiconductor light emitting device 1.

By setting the wavelength of light radiated from the light conversion member dispersed in the sealing member 15 (fluorescence) to a wavelength with high reflectivity in reflection characteristics of metal plating with corrosion resistance, it is possible to improve a light output of the semiconductor light emitting device 1.

### (Shape and Material of Adhesive Member)

Hereinafter, a shape and the like of the adhesive member 13 for improving reflection efficiency of sub-light will be described in detail.

The adhesive member 13 is disposed below the light emitting element 12 to adhere the light emitting element 12 to the upper surface of the first electrode 11a and also extends to the outside of the external shape of the rectangle of the light emitting element 12 to reflect the sub-light emitted from the side surfaces of the light emitting element 12.

The shape of the edge of the adhesive member 13 is a rectangle with rounded corners and is larger than the light emitting element 12, as in FIG. 1(a). When the adhesive member 13 is viewed from above, the edge of the adhesive member 13 forms a fan shape of which one side of the light emitting element 12 is the base (a shape of an isosceles triangle with rounded corners) or a parabolic shape.

In other words, centers O of the adhesive member 13 and the light emitting element 12 coincide and positions of the corners of the adhesive member 13 are deviated by 45 degrees from positions of the corners of the light emitting element 12. The shape of the edge of the adhesive member 13 may not be a perfect rectangle with rounded corners and the sides of the rectangle may form a gentle curve bulging outward.

That is, a distance from one side of the external shape of the rectangle of the light emitting element 12 to the edge of the adhesive member is largest at a center of one side of the light emitting element 12 and decreases toward both ends of the one side.

A predetermined range of the edge of the adhesive member 13 including a position at which the distance from the one side of the light emitting element 12 is largest has a curved form, and forms rounded corners of the adhesive member 13.

In other words, the edge of the adhesive member 13 overhangs to the outermost side at the centers of four sides of the light emitting element 12 and becomes closest to the light emitting element 12 at the positions of each corner of the light emitting element 12.

By setting the shape of the adhesive member 13 to the above-described shape, it is possible to efficiently reflect the sub-light of the light emitting element 12 having intensity distribution as in FIG. 3(b). A bonding space BS provided to connect the bonding wires 14a and 14b to the first electrode 11a and the second electrode 11b and not covered with the adhesive member 13 can be secured in the first electrode 11a and the second electrode 11b.

An area of the entire adhesive member 13 is preferably twice or more an area of the bottom surface of the light emitting element 12.

Specifically, when a distance from the center O to a side of the light emitting element 12 is L1 (=½ of the length of one side) and a distance from the center O to each corner of the adhesive member 13 (an intersection X of virtual extension lines of adjacent sides of the adhesive member 13) is L2, the adhesive member 13 preferably satisfies a relationship of (2·(2L1)²≤(√2·2L)²). An upper limit is an area in which the bonding space BS is not eliminated or 3 times or less.

When the adhesive member 13 and the light emitting element 12 are viewed from above, a contour of the light emitting element 12 is preferably located inside the edge of the adhesive member 13. In particular, the edge of the adhesive member 13 is preferably on the outside from each corner of the light emitting element 12 by a width W that is 0.1 times the length of one side of the light emitting element 12 (0.1·2L1≤W).

Therefore, as illustrated in FIG. 4(a), a distance L3 from the light emitting element 12 to the edge of the adhesive member 13 at the center of one side of the light emitting element 12 (a distance between the center O and the intersection X) is preferably equal to or greater than the distance L1 from the center O to the side of the light emitting element 12 (=½ of the length of one side).

A region located below the light emitting element 12 (bottom surface) in the adhesive member 13 has a thickness by which the light emitting element 12 can be adhered to the first electrode 11a at a predetermined strength and by which light emitted from the lower surface of the light emitting element 12 is reflected to be incident again inside the light emitting element 12.

As illustrated in FIG. 4 (b), the cross-sectional shape of the region of the adhesive member 13 outside of the light emitting element 12 has a bulged shape. That is, the cross-sectional shape of the adhesive member 13 extends from a position coming into contact with the side surface of the light emitting element 12 to rise above a plane parallel to the surface of the first electrode 11a, is lowered at the edge of the adhesive member 13, and reaches the surface of the first electrode 11a. A height of a portion of the adhesive member 13 coming into contact with the side surface of the light emitting element 12 is ⅓ or less of the height of the light emitting element 12. Accordingly, the light output of the light emitting device 1 can be improved without blocking the sub-light emitted from the side surfaces of the light emitting element 12.

The adhesive member 13 is formed of composite resin in which photoreflective particles are dispersed in transmissive medium resin.

As the medium resin, transparent polysilsesquioxane (siloxane compound) resin can be used that has hardness to not alleviate a bonding pressure in wire bonding performed after the light emitting element 12 is adhered to the first electrode 11a of the lead frame (the first electrode 11a and the second electrode 11b). In addition to the resin, trioxysilane-based silsesquioxane derivative resin can also be used.

As the photoreflective particles, titanium oxide particles with a particle size of 5 nm to 500 nm can be used. The particles reflect visible light from bule to red (diffuse reflection). By setting a particle size of the photoreflective particles to have a distribution broader than a particle size in a Mie scattering region (200 nm to 300 nm in visible light), particles with smaller particle sizes enter between particles with large particle sizes, and thus the hardness of the adhesive member 13 can be improved. Further, high reflectivity can be obtained. As the photoreflective particles, alumina (Al₂O₃), zinc oxide (ZnO), or the like may also be used.

### (Shape and Material of First and Second Electrodes)

The first electrode 11a and the second electrode 11b (the lead frames) have the shapes illustrated in FIGS. 1 and 5, a core is copper (Cu) or a copper alloy and a plated layer in which a nickel layer and a gold layer are stacked in this order (Ni/Au) is formed on the surface thereof. As the core, aluminum (Al), an aluminum alloy, an iron-nickel alloy (Fe—Ni 42%, Fe—Ni 29%-Co 17%), or the like can also be used.

### (Shape and Material of Frame)

The frame 10 is resin in which photoreflective particles are dispersed formed in a shape that has a depression at the center as in FIG. 1 by a technique such as insert molding.

As the resin, for example, dioxide silane-based silicone resin, epoxy resin, or acrylic resin can be used.

As the photoreflective particles, titanium oxide particles with a particle size of, for example, 200 nm to 300 nm can be used. Additives such as short glass fibers or nanosilica particles may be added.

### (Shape and Material of Light Emitting Element)

The light emitting element 12 may have any structure as long as light with a desired wavelength is emitted from the upper surface and the side surfaces and blue light is emitted. Here, the light emitting element that emits blue light, as illustrated in FIG. 2, is adopted. The effect of the present invention is also improved according to an increase in the sub-light emitted from the side surfaces of the light emitting element.

The light emitting element 12 in FIG. 2 has a structure in which a transparent substrate (sapphire) is used as a growth substrate 22, on which an n-type nitride layer serving as an n-type semiconductor layer 23, a multi-quantum well (MQW) light emitting layer 24, a p-type nitride layer serving as a p-type semiconductor layer 25, and a transparent p-side electrode 26 are stacked. The p-side electrode pad (anode) 21b is mounted on part of the upper surface of the transparent p-side electrode 26. The n-side electrode pad 21a that has a function of an n-side electrode is mounted on an exposed part of the upper surface of the n-type semiconductor layer 23. A region not covered by the p-side electrode pad 21b and the n-side electrode pad 21a of the upper surface is covered with a protective film 28. An element reflection layer 27 of a reflective dielectric multilayer film or metal may be disposed on the lower surface of the growth substrate 22 as necessary.

### (Material of Sealing Member)

In the sealing member 15, a wavelength conversion member is dispersed in medium resin transmitting light emitted from the light emitting element 12. Here, silicone resin was used as the medium resin and a YAG green-yellow phosphor was used as the wavelength conversion member.

As the medium resin, any of silicone resin, epoxy resin, and acrylic resin can be used.

As the wavelength conversion member, a member in which blue light emitted from the light emitting element 12 is absorbed to be excited and light with a longer wavelength than blue-green light is radiated can be selected for use. For example, LuAG green phosphor, n-type SiALON green phosphor, CASN red phosphor, S-CASN red phosphor, KFS red phosphor, YAG green-yellow phosphor, or orthosilicate green-yellow phosphor can be used. Cadmium selenide (CdSe)-based nanoparticles, indium phosphide (InP)-based nanoparticles, or an indium nitride (InN)-based quantum dot (QD) wavelength conversion material can also be used. The QD wavelength conversion material may be applied directly to the surface of the light emitting element 12.

### (Manufacturing Method)

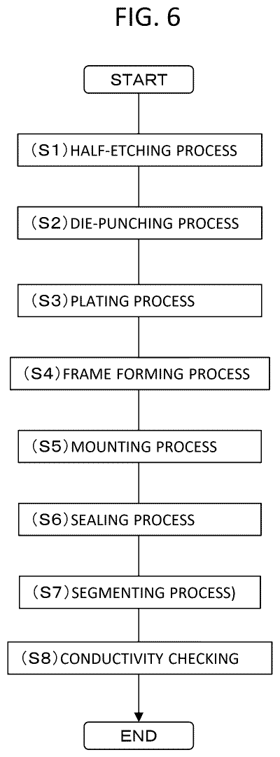

A method for manufacturing the semiconductor light emitting device 1 according to the first embodiment will be described with reference to the processing diagram of FIG. 6 and FIGS. 7 to 15. Here, an example in which the first electrode 11a and the second electrode 11b are subjected to Au plating will be described.

### (Step S1: Half-Etching Process)

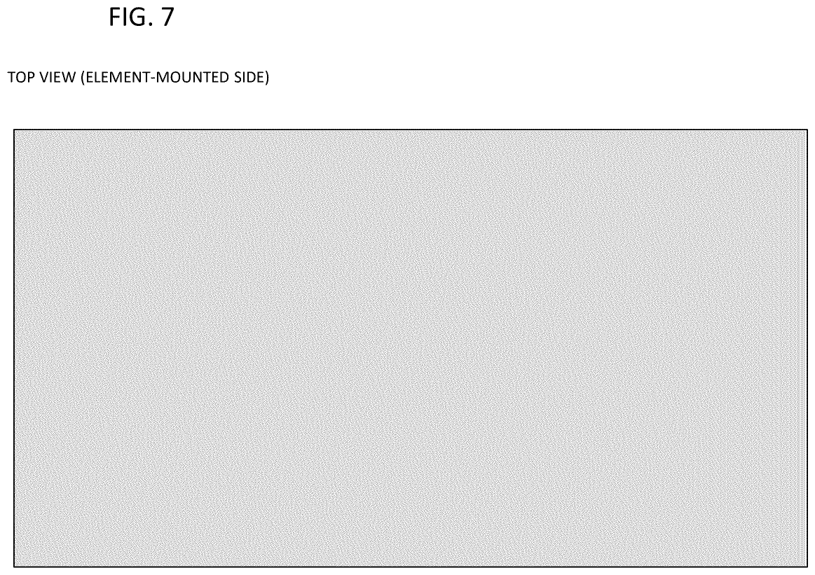

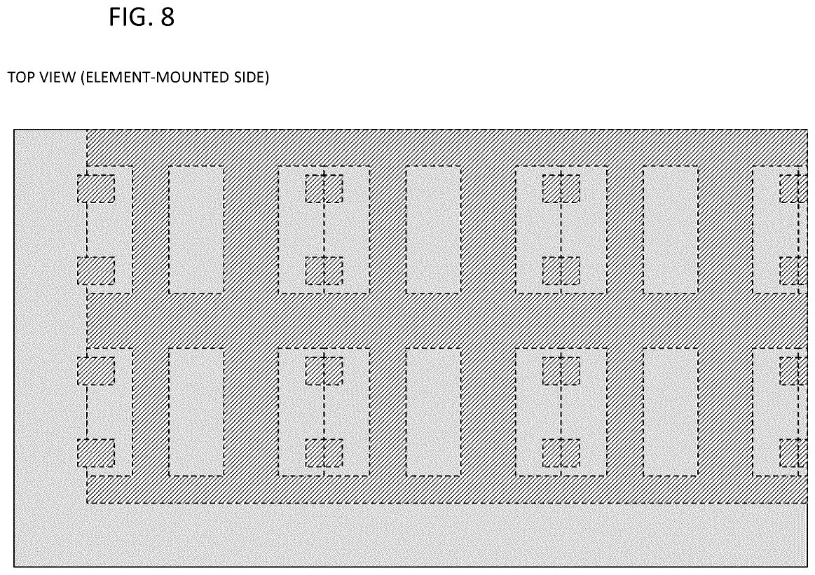

As in FIG. 7, a copper plate is prepared and a resist mask is formed on a rear surface of the copper plate as in FIG. 8 so that a region to be half-etched is exposed. The etching is performed using an etchant until the thickness of the copper plate becomes about half.

### (Step S2: Die-Punching Process)

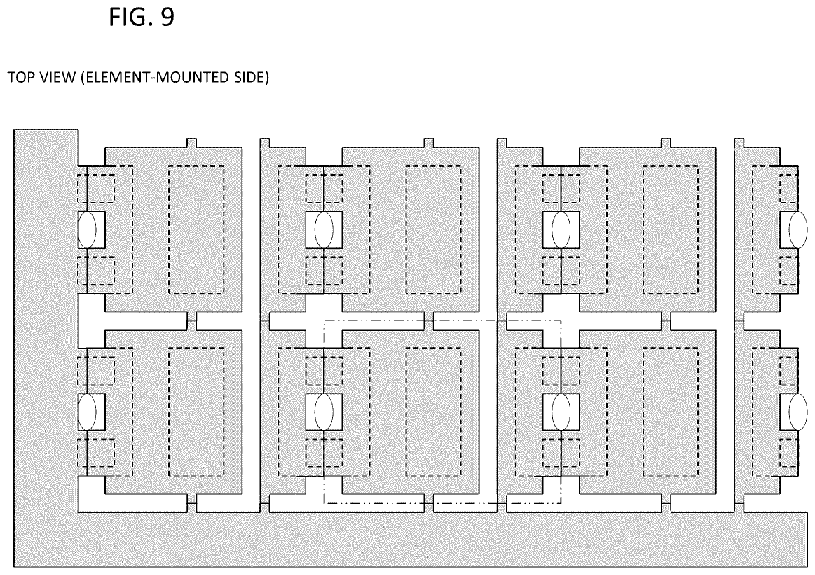

As in FIG. 9, predetermined regions of the copper plate are punched and removed with a mold to form regions that become the first electrode 11a and the second electrode 11b. Accordingly, a lead frame in which the plurality of first electrodes 11a and second electrodes 11b continue is formed.

Instead of punching, the predetermined regions may be removed by etching to form the lead frame. Here, a resist mask covering the regions of the first electrode 11a and the second electrode 11b is formed. A region not covered with the resist mask may be etched until the copper plate disappears.

### (Step S3: Plating Process)

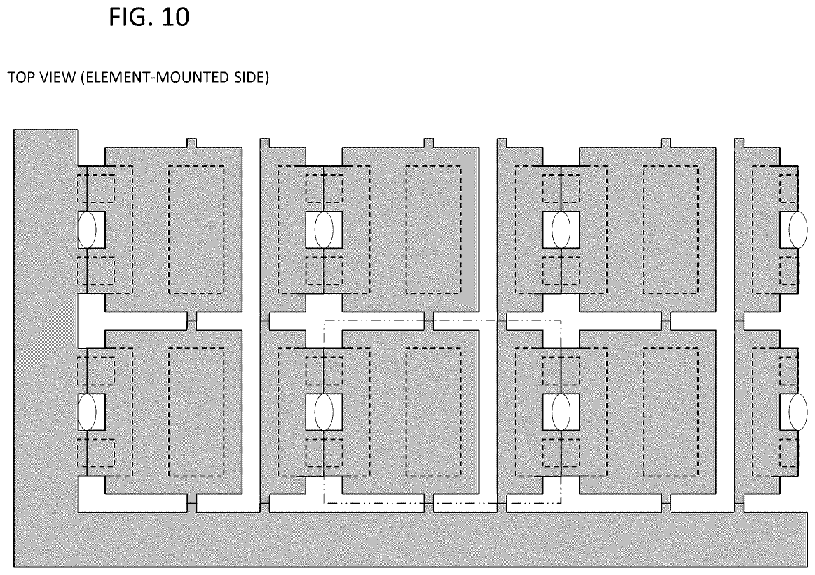

As in FIG. 10, the surface of the lead frame is plated in order of Ni and Au.

### (Step S4: Frame Forming Process)

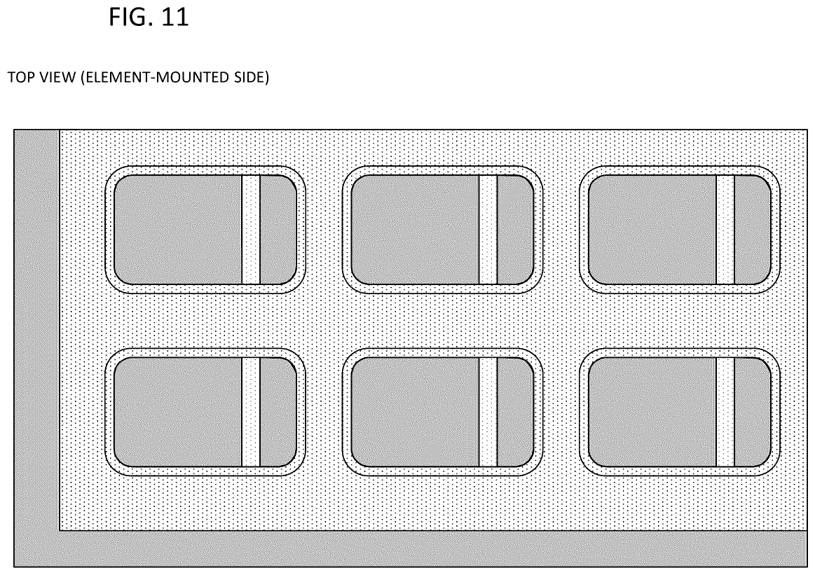

The frame 10 is formed by insert molding in which the lead frame is interposed in a mold, resin in which photoreflective particles are dispersed is heated and poured, and subsequently the resin is cured, as in FIG. 11.

### (Step S5: Mounting Process)

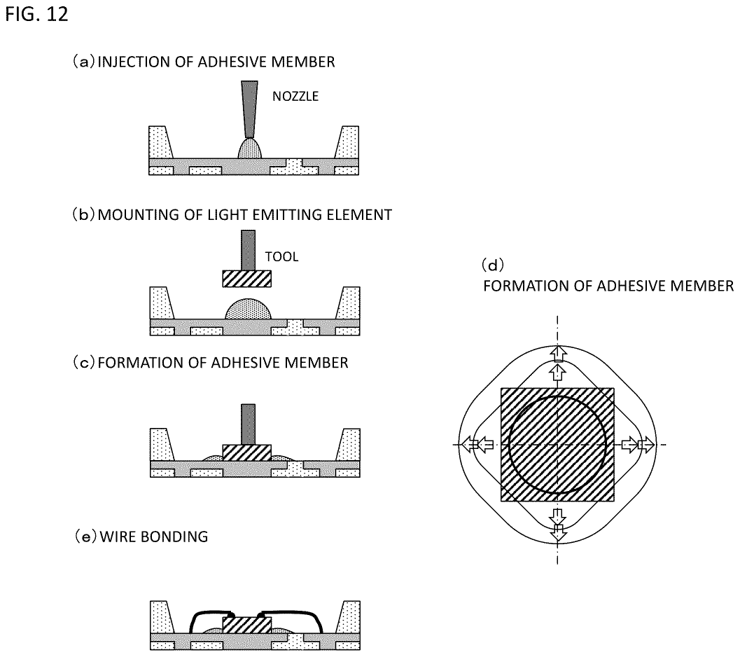

As in FIG. 12(a), the resin that becomes the adhesive member 13 in which photoreflective particles are dispersed is applied to the upper surface of the first electrode 11a in an uncured state. Here, a predetermined amount of resin is applied using a nozzle or the like so that the area of the spread adhesive member 13 is about twice the area of the light emitting element 12 when the adhesive member 13 is spread by pressing with the light emitting element 12.

As in FIG. 12(b), the light emitting element 12 is held with a tool and is slowly mounted and pressed on the uncured adhesive member 13. Accordingly, as in FIGS. 12(c) and (d), the uncured adhesive member 13 can be spread not only immediately below the light emitting element 12 but also to the outside of the light emitting element 12. Here, a cross-sectional shape of the adhesive member 13 in the region outside of the light emitting element 12 rises in a bulged shape. When ultrasonic vibration is applied here, the adhesive member can be spread outward while inhibiting rise of a bulge of the cross-sectional shape. Alternatively, a similar effect can be obtained by roughening the surface to which the adhesive member 13 is applied by blowing.

Subsequently, the adhesive member 13 is cured by heating (for example, 150° C. for 30 minutes), so that the adhesive member 13 is formed extending to the outside of the light emitting element 12 in a predetermined shape.

Accordingly, the centers O of the adhesive member 13 and the light emitting element 12 substantially coincide. The adhesive member 13 can be formed in a substantially rectangular shape having rounded corners when viewed from above and a shape of which the position of the corners are deviated by 45 degrees from the positions of the corners of the light emitting element 12.

Subsequently, as in FIG. 12 (e), bumps are formed on the upper surfaces of the p-side electrode pad 21b and the n-side electrode pad 21a of the light emitting element 12. Thereafter, the first bonding wire 14a and the second bonding wire 14b are wire-bonded to connect the p-side electrode pad 21b and the n-side electrode pad 21a by the first electrode 11a, the second electrode 11b, the first bonding wire 14a, and the second bonding wire 14b.

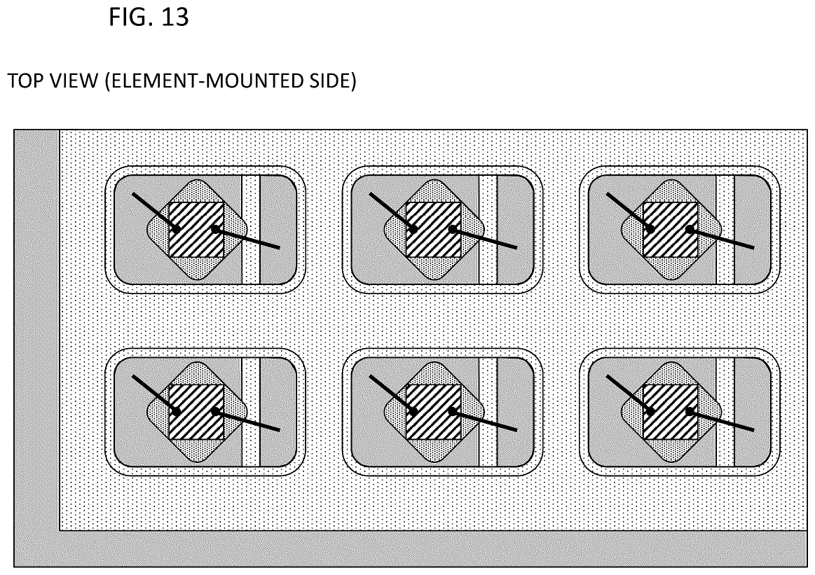

Accordingly, as in FIG. 13, the light emitting element 12 is mounted on the first electrode 11a and the second electrode 11b, and the adhesive member 13 is formed extending to the outside of the light emitting element 12 in a predetermined shape.

### (Step S6: Sealing Process)

The uncured sealing member 15 in which phosphor is dispersed is injected into the depression of the frame 10 to bury the periphery of the light emitting element 12, the exposed upper surface of the adhesive member 13, the exposed upper surfaces of the first electrode 11a and the second electrode 11b, the first bonding wire 14a, and the second bonding wire 14b.

Thereafter, the sealing member 15 is cured by a heating process (for example, 150° C. for 30 minutes to 150 minutes).

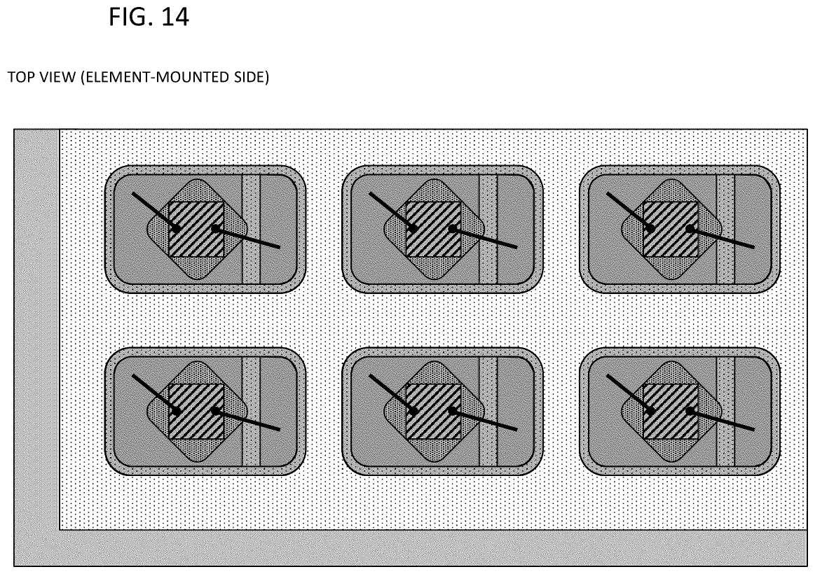

Accordingly, a continuum in which the plurality of semiconductor light emitting devices 1 continue with the lead frame and the frame 10 is formed as in FIG. 14.

### (Step S7: Segmenting Process)

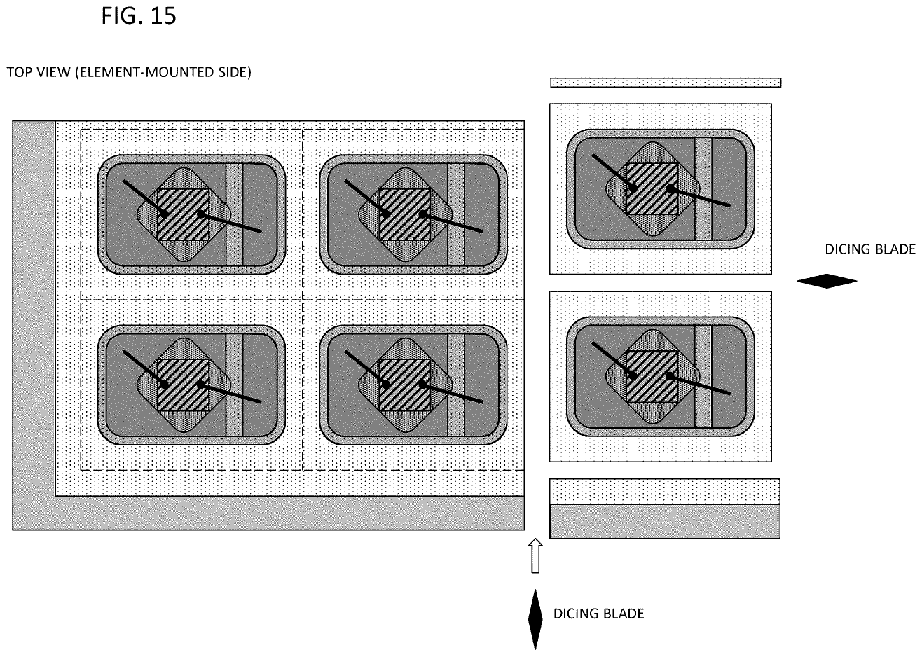

As in FIG. 15, segmentation is performed by dicing along the external shapes of the individual semiconductor light emitting devices 1.

### (Step S8: Conductivity Checking Process)

Finally, conductivity checking is performed on the individual semiconductor light emitting devices 1 to complete the semiconductor light emitting device 1.

As such, in the process of manufacturing the semiconductor light emitting device 1 according to the embodiment, an application amount of the adhesive member 13 is designed in advance and the adhesive member 13 is pressed and spread by the light emitting element 12 in the uncured state, so that the positions of the centers O of the adhesive member 13 and the light emitting element 12 coincide, and the adhesive member 13 can be formed in a shape that is a rectangular shape with rounded corners and of which the positions of the corners are deviated by 45 degrees from the positions of the corners of the light emitting element 12.

### Comparative Example 1

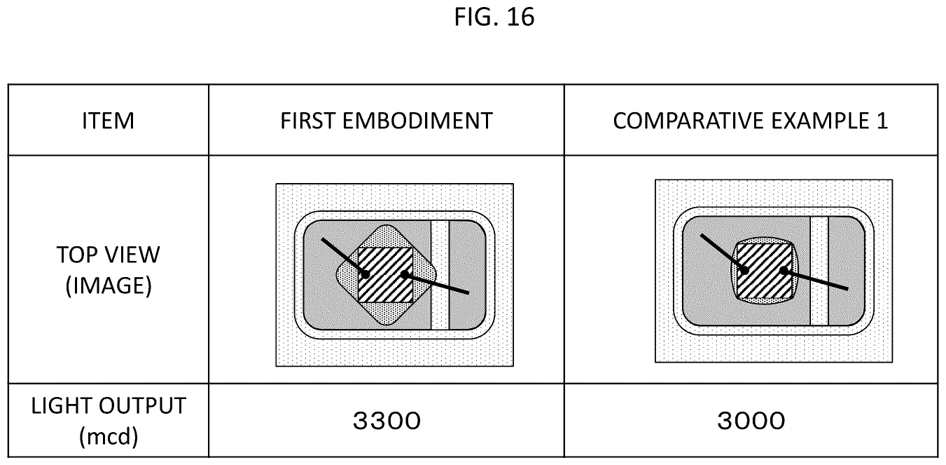

In a semiconductor light emitting device according to Comparative Example 1, as shown in the right figure of FIG. 16, an amount of the adhesive member 13 by which sufficient adhesion strength for adhering the light emitting element 12 with the upper surface of the first electrode 11a (appropriate adhesion amount) was set. The adhesive member 13 of the set amount protrudes by a width about equal to the height of the light emitting element 12 from the side surfaces of the light emitting element 12 when viewed from above. The semiconductor light emitting device was manufactured by setting the uncured adhesive member 13 applied to the upper surface of the first electrode 11a to an appropriate adhesion amount in the mounting process of step S5.

### (Light Outputs of First Embodiment and Comparative Example 1)

A light output of the semiconductor light emitting device according to the first embodiment and a light output of the semiconductor light emitting device according to Comparative Example 1 were measured. The light output of the semiconductor light emitting device according to the first embodiment was 3300 mcd and the light output of the semiconductor light emitting device according to Comparative Example 1 was 3000 mcd. Thus, it was confirmed that the light output of the semiconductor light emitting device 1 according to the embodiment was greater by 10% or more.

The result is because part of the sub-light emitted from the side surfaces of the light emitting element 12 is absorbed by the surface of the first electrode 11a (Au) and

the light output of the light emitting device decreases in the semiconductor light emitting device according to Comparative Example 1 compared to the semiconductor light emitting device according to the first embodiment.

### Second Embodiment

A semiconductor light emitting device according to a second embodiment has a structure in which Au is replaced with Ag on the outermost surfaces of the first electrode 11a and the second electrode 11b of the semiconductor light emitting device 1 according to the first embodiment. The semiconductor light emitting device can be manufactured by performing Ni/Ag plating on the first electrode 11a and the second electrode 11b in the plating process of the Step S3.

### Comparative Example 2

A semiconductor light emitting device according to Comparative Example 2 has a structure in which Au is replaced with Ag on the outermost surfaces of the first electrode 11a and the second electrode 11b of the semiconductor light emitting device 1 according to the first embodiment and the adhesive member 13 has a shape protruding by a width about equal to the height of the light emitting element 12 from the side surfaces of the light emitting element 12 when viewed from above. In other words, Au is replaced with Ag on the surfaces of the first electrode 11a and the second electrode 11b of the semiconductor light emitting device 1 according to Comparative Example 1. The semiconductor light emitting device can be manufactured by performing Ni/Ag plating on the first electrode 11a and the second electrode 11b in the plating process of step S3 and setting an adhesion amount of the uncured adhesive member 13 to be applied to the upper surface of the first electrode 11a to an appropriate amount in the mounting process of step S5.

### (Light Outputs of Second Embodiment and Comparative Example 2)

The semiconductor light emitting device according to the second embodiment and the semiconductor light emitting device according to Comparative Example 2 was subjected to a sulfidation test in conformity with JEITA ED-4912A and corroded and a light output before and after the corrosion was measured. The result is shown in Table 1.

TABLE 1

| | Plated | | | | |
|---|---|---|---|---|---|
| | outermost | | White | | |
| | layer of | Corrosion | die-attach | | |
| Invention | lead frame | resistance | material | Reflectivity | Result |
| Second | Silver: Ag | Weak (darkened | Yes | High in entire | Decrease to 85% |
| embodiment | | due to sulfidation) | | visible light band | of initial value due to |
| | | | | | sulfidation |
| Comparative | Silver: Ag | Weak (darkened | No | High in entire | Decrease to 58% |
| example 2 | | due to sulfidation) | | visible light band | of initial value due to |
| | | | | | sulfidation |

As in Table 1, reflectivity of a visible light band of the first electrode 11a and the second electrode 11b plated with Ag (lead frames) is high, but the electrodes are darkened due to sulfidation (corrosion) and the reflectivity decreases. In the semiconductor light emitting device according to the second embodiment, 85% of the light output was maintained compared to before the corrosion. In contrast, in the semiconductor light emitting device of Comparative Example 2, the light output was decreased to 58% compared to before the corrosion.

The reason why the decrease in the light output of the semiconductor light emitting device according to the second embodiment is suppressed to 85% is that reflection of sub-light emitted from the side surfaces of the light emitting element 12 remains in the adhesive member 13 due to the structure in which the adhesive member 13 extends from the side surfaces of the light emitting element 12. In other words, degradation can be limited to a part proportional to an area of contact of the first electrode 11a and the second electrode 11b corroded (darkened) due to sulfidation with the sealing material 15.

As such, in the semiconductor light emitting device according to the second embodiment, the sub-light emitted diagonally downward among the sub-light emitted from the side surfaces of the light emitting element 12 is reflected by the adhesive member 13. Therefore, even when the first electrode 11a and the second electrode 11b are corroded by oxygen, moisture, nitrogen oxide, sulfur oxide, or the like in the atmosphere, the semiconductor light emitting device is rarely susceptible to an influence of a decrease in reflectivity. Accordingly, light output of the semiconductor light emitting device can inhibit a decrease.

As described above, in the semiconductor light-emitting device according to the embodiment, part of the light emitted from the side surfaces of the light emitting element is reflected from the photoreflective connection member that extends outside of the light emitting element. Accordingly, the light output can be maintained even in a structure in which gold plating is performed on the lead frame for corrosion prevention. Even in a structure in which gold plating for corrosion prevention is not performed, the semiconductor light emitting device that is rarely susceptible to an influence of a decrease in reflectivity due to corrosion of the surface of the lead frame and a light output is maintained.

The technique for the semiconductor light emitting device according to the embodiment can be applied generally to an epoxy molding compound (EMC) package, a silicone molding compound (SMC) package, and the like.

### REFERENCE SIGNS LIST

O: center
W: width
1: semiconductor light emitting device
10: frame
11a: electrode
11b: electrode
12: light emitting element
13: adhesive member
14a: first bonding wire
14b: second bonding wire
15: sealing member
21a: n-side electrode pad
21b: p-side electrode pad
22: growth substrate
23: n-type semiconductor layer
24: light emitting layer
25: p-type semiconductor layer
26: p-side electrode
27: element reflection layer
28: protective film

1. A semiconductor light emitting device comprising:
a resin molded body having a depression;
a pair of electrodes disposed inside the resin molded body and formed of a lead frame in which a part of a surface is exposed from a bottom portion of the depression;
a light emitting element mounted on a first electrode in the pair of electrodes exposed from the bottom portion of the depression; and
an insulating connection member configured to adhere a bottom surface of the light emitting element to an upper surface of the first electrode, wherein
the connection member is photoreflective, and
the connection member has a shape extending to a region outside of an external shape of a rectangle of the light emitting element and covers a part of a region of a surface of the first electrode outside of the light emitting element.

2. The semiconductor light emitting device according to claim 1, wherein an external shape of the connection member is a rectangle with rounded corners and is larger than the light emitting element, central positions of the connection member and the light emitting element coincide, and positions of the corners of the connection member are deviated by 45 degrees from positions of corners of the light emitting element.

3. The semiconductor light emitting device according to claim 1, wherein a distance from one side of the external shape of the rectangle of the light emitting element to an edge of the connection member is largest at a center of one side of the light emitting element and decreases toward both ends of the one side.

4. The semiconductor light emitting device according to claim 3, wherein a predetermined range of the edge of the connection member including a position at which the distance from the one side of the external shape of the rectangle of the light emitting element is largest has a curved form.

5. The semiconductor light emitting device according to claim 1, wherein an entire area of the connection member is twice or more an area of the bottom surface of the light emitting element.

6. The semiconductor light emitting device according to claim 1, wherein a cross-sectional shape of the connection member in a region outside of the light emitting element is a bulged shape.

7. The semiconductor light emitting device according to claim 1, wherein photoreflective particles are dispersed in the connection member.

8. The semiconductor light emitting device according to claim 1, wherein upper surfaces of the pair of electrodes exposed from the bottom portion of the depression is subjected to sliver plating.

9. The semiconductor light emitting device according to claim 1, wherein upper surfaces of the pair of electrodes exposed from the bottom portion of the depression is subjected to gold plating.

10. The semiconductor light emitting device according to claim 1, wherein
a pair of element electrodes are provided on an upper surface of the light emitting element,
one of the pair of element electrodes is connected to a portion on the surface of the first electrode not covered with the connection member via a conductive wire, and
the other of the pair of element electrodes is connected to a surface of a second electrode of the pair of electrodes via the conductive wire.

11. The semiconductor light emitting device according to claim 1, wherein a space between the resin molded body and the light emitting element is sealed by sealing resin transmitting light emitted from the light emitting element, and the sealing resin covers the connection member extending outward from the light emitting element and the surface of the electrode not covered by the connection member.

12. The semiconductor light emitting device according to claim 1, wherein sealing resin contains a light conversion member that absorbs part of light emitted from the light emitting element and radiates light with a longer wavelength than the absorbed light.

13. A method for manufacturing a semiconductor light emitting device, the method comprising:
a process of applying a predetermined amount of uncured photoreflective resin onto an electrode disposed inside a resin molded body having a depression and formed of a lead frame exposed from a bottom portion of the depression; and
a process of mounting a light emitting element on the uncured photoreflective resin, pressing and spreading the uncured photoreflective resin by the light emitting element, and adhering a bottom surface of the light emitting element to an upper surface of a first electrode while simultaneously forming a connection member that has a shape extending to a region outside of an external shape of a rectangle of the light emitting element and covers a part of a region of a surface of the electrode outside of the light emitting element.
